(19) United States
(12) Patent Application Publication
(10) Pub. No.: US 2026/0328804 A1
(43) Pub. Date: Oct. 22, 2026

(54) ELECTRICAL CONNECTION DEVICE

(71) Applicant: Kabushiki Kaisha Nihon Micronics, Tokyo (JP)

(72) Inventors: Souichi KANOSUE, Oita (JP); Masataka Kimoto, Oita (JP); Toshihisa Kadowaki, Oita (JP); Shin Sakiyama, Tokyo (JP)

(73) Assignee: Kabushiki Kaisha Nihon Micronics, Tokyo (JP)

(21) Appl. No.: 19/529,438

(22) Filed: Feb. 4, 2026

Related U.S. Application Data
(63) Continuation of application No. PCT/JP2024/023980, filed on Jul. 2, 2024.

(30) Foreign Application Priority Data
Aug. 9, 2023 (JP) 2023-130223

(51) Int. Cl. G01R 1/04; G01R 1/073

(52) U.S. Cl. CPC G01R 1/0441; G01R 1/073

(57) ABSTRACT

An electrical connection device includes: probes; a flexible wiring sheet connected to the probes; and a wiring substrate. Each probe has a tip portion arranged in contact with an inspection object and a base end portion coupled to the tip portion. The wiring sheet has first and a second sheet surfaces, first connection portions connected to the base end portions of the probes arranged on the first sheet surface, and second connection portions arranged on the second sheet surface. An internal circuit connecting the first connection portions and the second connection portions is formed between the first sheet surface and the second sheet surface. The wiring substrate has a first main surface on which first electrodes connected to the second connection portions are arranged, the first main surface facing the second sheet surface, and a second main surface on which second electrodes electrically connected to the first electrodes are arranged.

### CROSS-REFERENCE TO RELATED APPLICATIONS

The present application is a continuation of International Application No. PCT/JP2024/023980, filed on Jul. 2, 2024, and based upon and claims the benefit of priority from Japanese Patent Application No. 2023-130223, filed on Aug. 9, 2023, the entire contents of which are incorporated herein by reference.

### TECHNICAL FIELD

The present disclosure relates to an electrical connection device used for inspecting electrical characteristics of an inspection object.

### BACKGROUND ART

In order to measure electrical characteristics of an inspection object, such as an integrated circuit, an electrical connection device having an inspection terminal brought into contact with the inspection object is used. In measurement using the electrical connection device, the inspection object is electrically connected to an inspection device such as a tester through the inspection terminal.

In order to measure characteristics of an inspection object with high accuracy, it is important to propagate an electrical signal reduced in loss and noise to an electrical connection device. For example, in order to measure high-frequency characteristics with high accuracy, an electrical connection device provided with an electronic component such as a capacitor connected to signal wiring through which an electrical signal propagates has been considered.

### SUMMARY

An object of the present disclosure is to provide an electrical connection device capable of measuring characteristics of an inspection object with high accuracy.

### Solution to Problem

An electrical connection device according to an embodiment includes: inspection terminals, a flexible wiring sheet connected to the inspection terminals, and a wiring substrate. Each inspection terminal has a tip portion arranged in contact with an inspection object and a base end portion connected to the tip end portion. The wiring sheet has both sides defined by a first sheet surface and a second sheet surface, first connection portions connected to the base end portions of the inspection terminals are arranged on the first sheet surface, and second connection portions are arranged on the second sheet surface. An internal circuit that connects the first connection portions and the second connection portions is formed between the first sheet surface and the second sheet surface. The wiring substrate has a first main surface on which first electrodes connected to the second connection portions are arranged, the first main surface facing the second sheet surface, and a second main surface on which second electrodes electrically connected to the first electrodes are arranged.

According to the embodiment, it is possible to provide the electrical connection device capable of measuring characteristics of an inspection object with high accuracy.

### BRIEF DESCRIPTION OF DRAWINGS

FIG. 1 is a schematic view illustrating the configuration of an electrical connection device according to an embodiment.

FIG. 2 is a schematic plan view illustrating the configuration of the electrical connection device according to the embodiment.

FIG. 3 is a schematic cross-sectional view illustrating a structure example of a wiring sheet of the electrical connection device according to the embodiment.

FIG. 4 is a schematic view illustrating an example of an internal circuit of the wiring sheet of the electrical connection device according to the embodiment.

FIG. 5 is a schematic view illustrating another example of an internal circuit of the wiring sheet of the electrical connection device according to the embodiment.

FIG. 6 is a schematic view illustrating an example arrangement of an electronic circuit arranged in the electrical connection device according to the embodiment.

### DESCRIPTION OF EMBODIMENTS

Next, embodiments of the present disclosure will be described below with reference to the drawings. The same or similar elements illustrated in the drawings are denoted by the same or similar reference numerals. However, the drawings are illustrated schematically, and it should be noted that the proportions of the thicknesses or lengths of the respective parts and so forth are not drawn to scale. It should also be understood that the relationships or proportions of the dimensions between the respective drawings are different from each other in some elements. The embodiments described below exemplify a device and a method for embodying a technical idea of the present disclosure. In the embodiment of the present disclosure, the material, shape, structure, arrangement, manufacturing method and the like of the components are not limited to the following description.

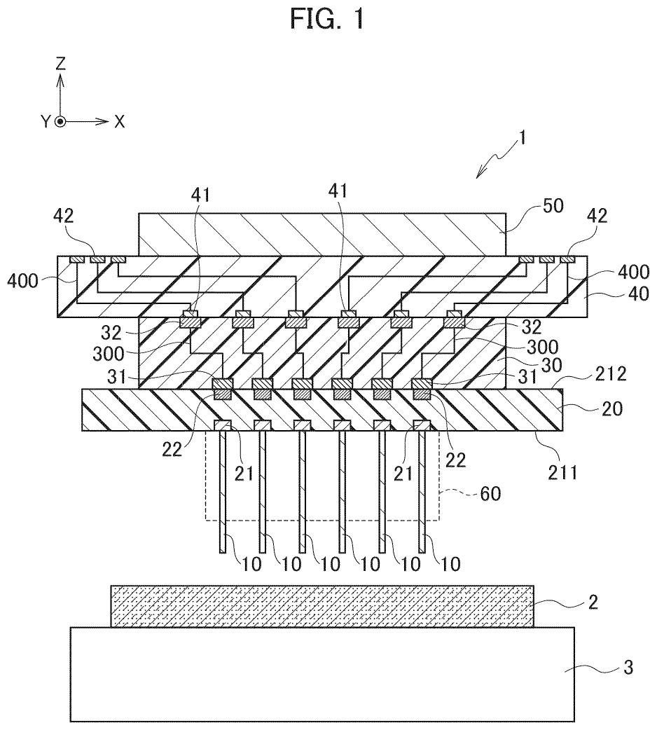

An electrical connection device 1 according to an embodiment illustrated in FIG. 1 is used for inspecting an inspection object 2. The electrical connection device 1 includes probes 10, a flexible wiring sheet 20 connected to the probes 10, a wiring substrate 30 laminated on the wiring sheet 20, and a printed substrate 40 laminated on the wiring substrate 30. In the following description, the direction in which the electrical connection device 1 is positioned as viewed from the inspection object 2 is referred to as an upward direction, and the direction in which the inspection object 2 is positioned as viewed from the electrical connection device 1 is referred to as a downward direction. Further, in the respective components of the electrical connection device 1, a surface facing upward is referred to as an upper surface, and a surface facing downward is referred to as a lower surface.

Each probe 10 functions as an inspection terminal that electrically connects the inspection object 2 and an inspection device (not illustrated) with each other. The probe 10 has one end portion (hereinafter referred to as a “tip portion”) that is arranged in contact with the inspection object 2 and the other end portion (hereinafter referred to as a “base end portion”) that is coupled to the tip portion. The probes 10 may be supported by a probe head 60 through which the probes 10 penetrate. The probe head 60 may be a housing provided with a space inside. The probe head 60 is fixed to, for example, the wiring sheet 20.

The wiring sheet 20 has both sides defined by a first sheet surface 211 and a second sheet surface 212. First connection portions 21 connected to the base end portions of the probes 10 are arranged on the first sheet surface 211 which is a lower surface of the wiring sheet 20. A second connection portion 22 are arranged on the second sheet surface 212 that is an upper surface of the wiring sheet 20 and facing the wiring substrate 30. Although not illustrated in FIG. 1, an internal circuit that connects the first connection portions 21 and the second connection portions 22 is formed between the first sheet surface 211 and the second sheet surface 212.

First electrodes 31 connected to the second connection portions 22 of the wiring sheet 20 are arranged on a first main surface of the wiring substrate 30 facing the second sheet surface 212. Second electrodes 32 electrically connected to the first electrodes 31 are arranged on a second main surface of the wiring substrate 30 facing the printed substrate 40. The second electrodes 32 are electrically connected to the first electrodes 31 via connection wirings 300, respectively. The connection wirings 300 may be, for example, internal wirings arranged inside the wiring substrate 30. A multilayer wiring substrate such as MLO (Multi-Layer Organic) or MLC (Multi-Layer Ceramic) may be used as the wiring substrate 30.

Wiring patterns 400 connected to the second electrodes 32 of the wiring substrate 30 are arranged on the printed substrate 40 that is arranged facing the second main surface of the wiring substrate 30. The wiring patterns 400 arranged inside and on the surface of the printed substrate 40 electrically connect the second connection portions 22 of the wiring substrate 30 to the inspection device. For example, first end portions 41 of the wiring patterns 400 are connected to the second electrodes 32 of the wiring substrate 30, and second end portions 42 of the wiring patterns 400 are electrically connected to the inspection device (not illustrated). The first end portions 41 are arranged on a lower surface of the printed substrate 40, and the second end portions 42 are arranged on an upper surface of the printed substrate 40.

The inspection object 2 is mounted on a stage 3. The electrical connection device 1 is relatively movable in the up-down direction with respect to the stage 3. Upon the inspection of the inspection object 2, the tip portions of the probes 10 come into contact with signal terminals (not illustrated) of the inspection object 2 by reducing the spacing between the electrical connection device 1 and the stage 3. FIG. 1 illustrates a state in which the probes 10 and the inspection object 2 are separated from each other.

The wiring substrate 30 may be a space transformer that transforms the spacing of the base end portions of the probes 10 to the spacing of the first end portions 41 of the printed substrate 40 when viewed from the normal direction of the main surface of the wiring substrate 30. By using the wiring substrate 30 as a space transformer, the base end portions of the probes 10 corresponding to the spacing of the signal terminals arranged on the inspection object 2 can be electrically connected to the wiring patterns 400 of the printed substrate 40 arranged to be spaced wider than the spacing of the base end portions. By increasing the spacing of the second end portions 42 of the wiring patterns 400 using the space transformer, the connection between the wiring patterns 400 of the printed substrate 40 and the inspection device is facilitated.

As illustrated in FIG. 1, a stiffener 50 may be laminated on the printed substrate 40. The stiffener 50 has a higher rigidity than the printed substrate 40, and ensures the mechanical strength of the electrical connection device 1 by preventing the printed substrate 40 from bending or the like. Further, the stiffener 50 may be used as a support for fixing each component of the electrical connection device 1. The printed substrate 40 may be fixed to the stiffener 50 by screws, for example.

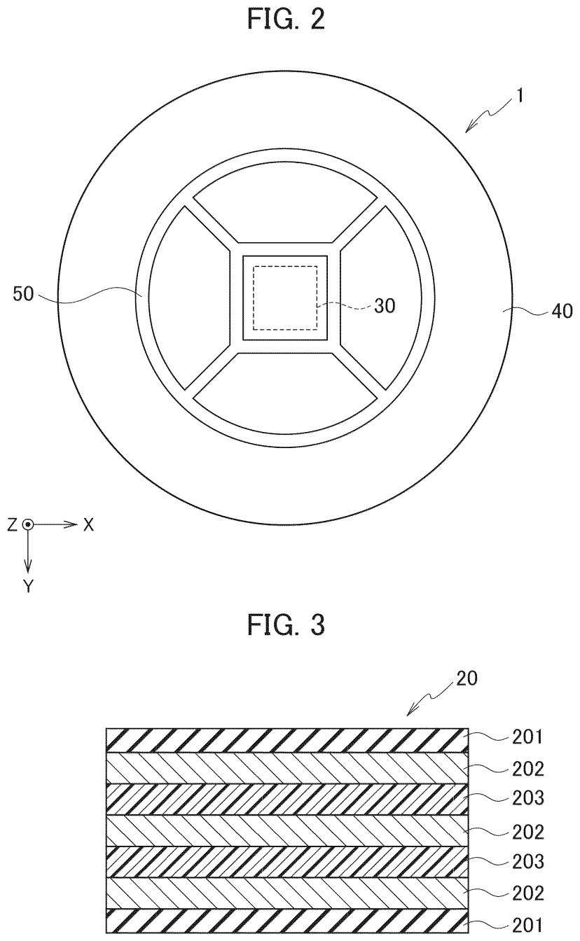

FIG. 2 is a plan view (hereinafter also referred to as “planar view”) of a structure in which the wiring sheet 20, the wiring substrate 30, the printed substrate 40, and the stiffener 50 are laminated, as seen from a Z direction. In FIG. 2, the Z direction is a depth direction of a page space, an X direction is a left-right direction of the page space, and a Y direction is an up-down direction of the page space.

The stiffener 50 is arranged on the upper surface of the printed substrate 40 which is circular in planar view. For example, as illustrated in FIG. 2, the stiffener 50 has a shape in which an outer circular ring and an inner rectangular ring are coupled by spokes. The wiring substrate 30 and the wiring sheet 20 are arranged near the center of the lower surface of the printed substrate 40. The wiring sheet 20, the wiring substrate 30, the printed substrate 40, and the stiffener 50 are fixed to each other by screws, for example.

A material having flexibility is used for the wiring sheet 20. Therefore, the wiring sheet 20 elastically deforms so as to urge the first connection portions 21 toward the base end portions when the first connection portions 21 receive pushing force from the base end portions of the probes 10. For example, the pushing force is generated from the base end portions of the probes 10 toward the first connection portions 21 when the tip portions of the probes 10 come into contact with the inspection object 2. In reaction to the pushing force, the wiring sheet 20 urges the first connection portions 21 toward the base end portions. Thus, the electrical connection device 1 has a preload function of pushing the probes 10 against the first connection portions 21 of the wiring sheet 20 upon the inspection of the inspection object 2. Therefore, in the electrical connection device 1, the contacts between the probes 10 and the inspection object 2 are stabilized, thereby enhancing the measurement accuracy of the inspection object 2.

The wiring sheet 20 may have a structure in which conductive films and insulating films are laminated. For example, an internal circuit may be constituted by conductive patterns formed on the conductive films. FIG. 3 illustrates a structure example of the wiring sheet 20. The wiring sheet 20 illustrated in FIG. 3 has a structure in which a laminated body of the conductive films 202 and the insulating films 203 is interposed between a pair of cover films 201 made of an insulating material. The number of lamination of the conductive films 202 and the insulating films 203 can be optionally set. Each conductive film 202 may be a metal material such as copper foil. Each insulating film 203 may be an insulating material such as a polyimide sheet. Each cover film 201 may be an insulating material such as a solder resist. For example, an adhesive may be used for bonding the conductive film 202, the insulating film 203, and the cover film 201 to each other. The wiring sheet 20 may have a structure in which a film made of an insulating material (also referred to as a “base film”) is further interposed between the laminated bodies each including the conductive film 202 and the insulating film 203.

According to the wiring sheet 20 illustrated in FIG. 3, it is possible to obtain both the flexibility due to the material quality of the wiring sheet 20 and the elasticity in the lamination direction due to the structure in which the conductive films 202 and the insulating films 203 are laminated. For this reason, according to the electrical connection device 1 including the wiring sheet 20, a preload function of pushing the first connection portions 21 of the wiring sheet 20 against the probes 10 works upon the inspection of the inspection object 2. As a result, the contact between the probes 10 and the inspection objects 2 is stabilized, thereby enhancing the measurement accuracy of the inspection object 2.

The internal circuit of the wiring sheet 20 may include, for example, a circuit (hereinafter also referred to as an “interposer circuit”) that electrically connects the first connection portions 21 and the second connection portions 22 with each other. For example, when an interposer circuit is formed on the wiring sheet 20 having the structure illustrated in FIG. 3, wiring is formed from the first sheet surface 211 to the second sheet surface 212, penetrating through the cover films 201, the conductive films 202, and the insulating films 203.

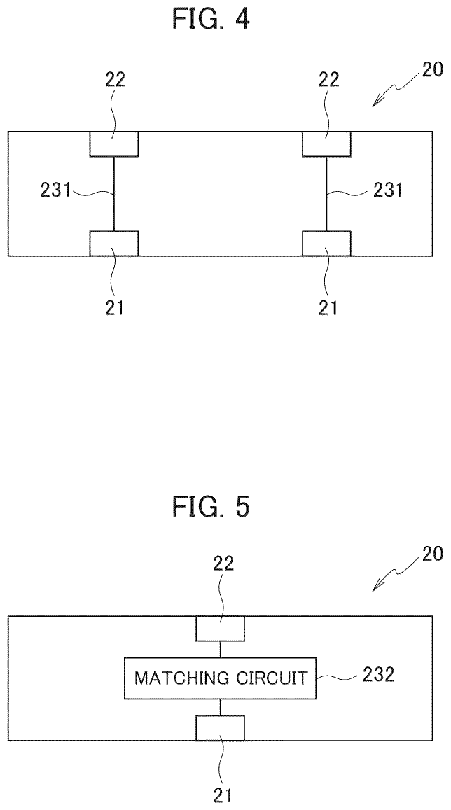

When the internal circuit of the wiring sheet 20 includes an interposer circuit, the internal circuit of the wiring sheet 20 may include a short-circuit wirings 231 that short-circuit the first connection portions 21 and the second connection portions 22, as illustrated in FIG. 4. In the electrical connection device 1 including the wiring sheet 20 having the internal circuit illustrated in FIG. 4, the inspection object 2 and the inspection device are electrically connected to each other via the probes 10, the internal circuit of the wiring sheet 20, the connection wirings 300 of the wiring substrate 30, and the wiring patterns 400 of the printed substrate 40. Thus, electrical signals are propagated between the inspection device such as an IC tester and the inspection object 2, and the characteristics of the inspection object 2 are measured. For example, the first connection portions 21 and the second connection portions 22 are respectively connected one to one by the internal circuit of the wiring sheet 20. Alternatively, the internal circuit may connect one first connection portion 21 to a plurality of second connection portions 22, or may connect a plurality of first connection portions 21 to one second connection portion 22.

As illustrated in FIG. 5, the internal circuit of the wiring sheet 20 may include a matching circuit 232 in which a first terminal is connected to the first connection portion 21 and a second terminal is connected to the second connection portion 22. The matching circuit 232 may be a circuit for impedance matching between the first connection portion 21 and the second connection portion 22. For example, the matching circuit 232 may include a π-type filter. By forming the matching circuit 232 in the internal circuit of the wiring sheet 20, the wiring length between the inspection object 2 and the matching circuit 232 can be shortened. Thus, for example, high-frequency measurement of the inspection object 2 can be stably performed.

The configuration of the internal circuit of the wiring sheet 20 is not of course limited to the above. For example, the internal circuit may include an electronic component such as a capacitor or an inductor. The electronic component included in the internal circuit of the wiring sheet 20 may be formed using, for example, a MEMS (Micro Electro Mechanical Systems) process. By using this MEMS process, a miniaturized element can be formed integrally with the wiring sheet 20. Further, the internal circuit may include a circuit (loopback circuit) that electrically connects any one of the first connection portions 21 and the other one of the first connection portions 21. Alternatively, the internal circuit of the wiring sheet 20 may include a circuit that switches between an interposer circuit that connects any one of the first connection portions 21 to any one of the second connection portions 22 and a loopback circuit that connects any one of the first connection portions 21 to the other one of the first connection portions 21.

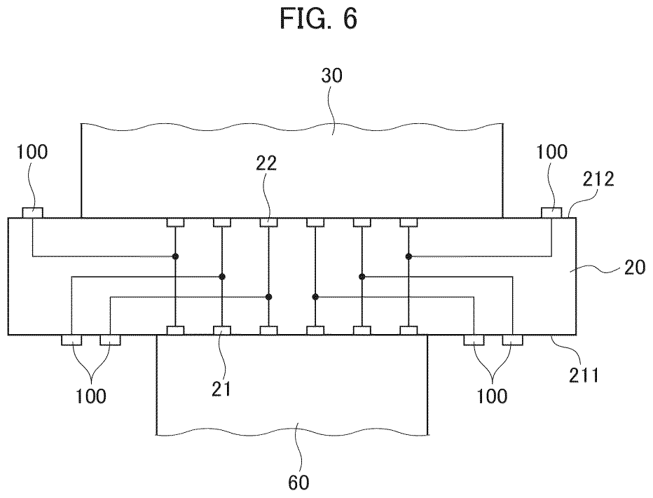

In the electrical connection device 1, electronic components electrically connected to the internal circuit can be arranged on the surface of the wiring sheet 20. For example, as illustrated in FIG. 6, the electronic components 100 connected to the internal circuit of the wiring sheet 20 may be arranged on each of the first sheet surface 211 and the second sheet surface 212. The electronic components 100 may be, for example, capacitors, inductors, or resistive elements. Although FIG. 6 illustrates an example in which the electronic components 100 are arranged on each of the first sheet surface 211 and the second sheet surface 212, the electronic components 100 may be arranged on either the first sheet surface 211 or the second sheet surface 212. By arranging the electronic components 100 on the surface of the wiring sheet 20, for example, electronic components arranged on the wiring substrate 30 or the printed substrate 40 can be reduced or distributed. Further, by arranging the electronic components 100 on the surfaces of the wiring sheet 20, the wiring length between the inspection object 2 and the electronic components 100 can be shortened. Therefore, for example, by arranging the electronic components 100 such as capacitors that reduces power supply noise on the wiring sheet 20, the measurement of the inspection object 2 can be stably performed.

Further, by making the area of the wiring sheet 20 larger than that of the wiring substrate 30 in planar view, as illustrated in FIG. 6, the electronic component 100 can be arranged on the remaining area of the second sheet surface 212 excluding the area joined to the wiring substrate 30. In contrast, in the electrical connection device not including the wiring sheet 20, an electronic component cannot be arranged on the second main surface of the wiring substrate 30 facing the printed substrate 40. Thus, according to the electrical connection device 1, the number of mounted electronic components can be increased.

As described above, the electrical connection device 1 according to the embodiment has a configuration in which the flexible wiring sheet 20 is arranged between the probes 10 and the wiring substrate 30. According to the electrical connection device 1, the contact between the probes 10 and the inspection object 2 is stabilized by the preload function obtained by the wiring sheet 20. As a result, the measurement accuracy of the inspection object 2 can be enhanced.

Further, according to the electrical connection device 1, the number of mounted electronic components can be increased. In addition, according to the electrical connection device 1, by arranging the electronic components near the inspection object 2, the wiring length between the inspection object 2 and the electronic components can be shortened. As a result, the measurement accuracy of the inspection object 2 can be enhanced.

Moreover, according to the electrical connection device 1, by arranging the flexible wiring sheet 20 between the probe head 60 and the wiring substrate 30, the warping and irregularities of the surfaces of the probe head 60 and the wiring substrate 30 can be absorbed by the wiring sheet 20. This prevents rattling and poor contact of the electrical connection device 1 caused by a gap generated between the probe head 60 and the wiring substrate 30.

### (Other Embodiments)

The embodiment of the present disclosure has been described above, but the statements and drawings forming part of this disclosure should not be understood as limiting the disclosure. Various alternative embodiments, examples, and operating techniques will be apparent to those skilled in the art from this disclosure.

For example, FIG. 1 illustrates a case where the electrical connection device 1 on which the wiring sheet 20 is mounted includes the probes 10 in contact with signal terminals of the inspection object 2. According to the electrical connection device 1 illustrated in FIG. 1, for example, it is possible to measure the electrical characteristics of the inspection object 2 in a state where it is not separated from the wafer or in a chipped state. Meanwhile, corresponding to the measurement of the electrical characteristics performed in a state where the inspection object 2 is mounted on a package or the like, the wiring sheet 20 may be mounted on the electrical connection device including a test socket. For example, instead of the probes 10 and the probe head 60 of the electrical connection device 1 illustrated in FIG. 1, a test socket in which an inspection terminal connectable to an external terminal of the package on which the inspection object 2 is mounted is provided may be arranged on the wiring substrate 30.

Thus, the present disclosure will of course include various embodiments and the like which are not described herein. Therefore, the technical scope of the present disclosure is defined only by the disclosure specifying matters according to the scope of claims reasonably derived from the above description.

1. An electrical connection device used for inspecting an inspection object, comprising:
inspection terminals, each inspection terminal having a tip portion arranged in contact with the inspection object and a base end portion coupled to the tip portion;
a flexible wiring sheet having both sides defined by a first sheet surface and a second sheet surface, in which first connection portions connected to the base end portions of the inspection terminals are arranged on the first sheet surface, second connection portions are arranged on the second sheet surface, and an internal circuit connecting the first connection portions and the second connection portions is formed between the first sheet surface and the second sheet surface; and
a wiring substrate having a first main surface on which first electrodes connected to the second connection portions are arranged, the first main surface facing the second sheet surface, and a second main surface on which second electrodes electrically connected to the first electrodes are arranged.

2. The electrical connection device according to claim 1, further comprising an electronic component arranged on at least one of the first sheet surface and the second sheet surface of the wiring sheet and electrically connected to the internal circuit.

3. The electrical connection device according to claim 1, wherein the wiring sheet has a structure in which a laminated body of conductive films and insulating films is interposed between cover films made of an insulating material.

4. The electrical connection device according to claim 1, wherein the wiring sheet elastically deforms so as to urge the first connection portions toward the base end portions when the first connection portions receive a pushing force from the base end portions.

5. The electrical connection device according to claim 4, wherein the pushing force is generated from the base end portions toward the first connection portions when the tip portions of the inspection terminals come into contact with the inspection object.

6. The electrical connection device according to claim 1, further comprising a printed substrate arranged facing the wiring substrate, the printed substrate having wiring patterns connected to the second electrodes arranged thereon.

7. The electrical connection device according to claim 6, wherein the wiring substrate is a space transformer for transforming spacing of the inspection terminals to spacing of the wiring patterns of the printed substrate when viewed from a normal direction of a main surface of the wiring substrate.

8. The electrical connection device according to claim 1, wherein the inspection terminals are probes, each probe having one end portion that is arranged in contact with a signal terminal of the inspection object, and the other end portion that is connected to a corresponding first connection portion of the wiring sheet.

9. The electrical connection device according to claim 1, wherein the inspection terminals are arranged in a test socket that is connected to an external terminal of a package on which the inspection object is mounted.
